(19) United States
(12) Patent Application Publication
(10) Pub. No.: US 2006/0131067 A1
(43) Pub. Date: Jun. 22, 2006

(54) PCB, manufacturing method thereof and semiconductor package implementing the same

(76) Inventors: Hyung-Jik Byun, Cheonan-si (KR); Yun-Chong Lee, Cheonan-si (KR)

Correspondence Address: HARNESS, DICKEY & PIERCE, P.L.C., P.O. BOX 8910, RESTON, VA, 20195, US

(21) Appl. No.: 11/145,999

(22) Filed: Jun. 7, 2005

(30) Foreign Application Priority Data
Dec. 20, 2004 (KR) 2004-108782

(51) Int. Cl. H05K 1/03

(52) U.S. Cl. 174/260; 174/255; 174/258

(57) ABSTRACT

A method may involve providing a substrate body having an upper surface and a lower surface. Circuit layers may be provided on the upper and the lower surfaces of the substrate body. A prepreg layer may be provided on the upper surface of the substrate body. The prepreg layer may cover the circuit layer on the upper surface. A PCB may be manufactured according to the method. The PCB may be implemented in a semiconductor package.

### PRIORITY STATEMENT

This U.S. non-provisional application claims benefit of priority under 35 U.S.C. §119 from Korean Patent Application No. 2004-108782, filed on Dec. 20, 2004, the entire contents of which are incorporated herein by reference.

### BACKGROUND

1. Field of the Invention

The present invention relates in general to a printed circuit board (“PCB”), a manufacturing method thereof, and a semiconductor package implementing the same and, more particularly, to a PCB that may reduce moisture absorption characteristics and improve the interfacial adhesion between component parts, a manufacturing method thereof, and a semiconductor package implementing the same.

2. Description of the Related Art

A trend may be to provide electronic products having characteristics of light weight, miniaturization, increased operating speeds, multi-functions, increased performance, increased reliability, and reduced production costs. The design of such products may be facilitated via package assembly technologies. An example package is known as a ball grid array (“BGA”) package.

A BGA package may provide a reduced mounting area on a circuit board (e.g., a motherboard) and improved electrical characteristics, as compared to other conventional packages (e.g., a plastic package). The BGA package may implement a PCB, instead of a lead frame that may be implemented in a conventional plastic package. The PCB may provide an increased mounting density on the motherboard because the entire surface of the PCB, which faces away from a semiconductor chip, may be available to support solder bumps, for example.

As shown in FIGS. 1 and 2, a conventional PCB 50 of a BGA package may include copper circuit layers 20 provided on an upper surfaces 12 and a lower surface 14 of a substrate body 10.

The substrate body 10 may be fabricated from prepreg material. As is well known in this art, prepreg may be a reinforcement material (e.g., a sheet, a tape, a tow, a fabric, or a mat) preimpregnated with resin and capable of storage for later use. The copper circuit layers 20 may be provided, for example, by attaching copper foils to the upper and the lower surfaces 12 and 14 and patterning the foils. The copper circuit layers 20 may include an upper circuit layer 22 provided on the upper surface 12 of the substrate body 10 and a lower circuit layer 24 provided on the lower surface 14 of the substrate body 10. The upper circuit layer 22 may include substrate pads 23 that may be provided adjacent to a chip mounting area 13, which may be located (for example) in the center of the upper surface 12. The upper circuit layer 22 may be electrically connected to a semiconductor chip. The lower circuit layer 24 may include bump pads 25 on which solder bumps may be provided. The substrate pads 23 and the bump pads 25 may be electrically interconnected by via holes 30 piercing the substrate body 10.

Solder resist layers 40 may be provided on the upper and the lower surfaces 12 and 14. The solder resist layers 40 may protect the copper circuit layers 20. The substrate pads 23 and bump pads 25 may be exposed through the solder resist layers 40.

The solder resist layers 40 may be formed by applying photo solder resist (“PSR”), for example, onto the upper and the lower surfaces 12 and 14 of the substrate body 10, and patterning the PSR so that the substrate pads 23 and the bump pads 25 may be exposed.

FIG. 3 illustrates a conventional BGA package 100 implementing the PCB 50 of FIGS. 1 and 2. Referring to FIG. 3, a semiconductor chip 61 may be mounted on the chip mounting area 13 of the upper surface 12 of the PCB 50 via an adhesive 63. Chip pads 62 of the semiconductor chip 61 and the substrate pads 23 may be electrically interconnected by bonding wires 64. A resin sealing 65 (which may be formed by applying liquid molding compound, for example) may be provided to protect the semiconductor chip 61 and the bonding wires 64. Solder bumps 66 may be provided on the bump pads 25.

The adhesive 63 may be applied to the solder resist layer 40 provided on the chip mounting area 13 of the PCB 50.

PSR is a material that may be used to form the solder resist layers 40. Although PSR is generally thought to provide acceptable performance, it is not without shortcomings. For example, the PSR may have relatively high moisture absorption characteristics and/or relatively low adhesive strength, which may cause various problems.

More specifically, the solder resist layer 40 may absorb moisture contained in the resin sealing 65 during a manufacturing process of the BGA package 100, and may also absorb moisture supplied in a moisture absorption test that may be implemented to check (for example) the reliability of the BGA package 100. The absorbed moisture may deteriorate the desired characteristics of the interface between the solder resist layer 40 and other components (for example, the copper circuit layers 20, the resin sealing 65, and/or the adhesive 63). Such deterioration may occur more frequently, for example, in a semiconductor chip 61 having a multi-layer interface structure.

The absorption of moisture may decrease the interfacial adhesion between the solder resist layer 40 and the copper circuit layer 20. The moisture absorbed by the solder resist layer 40 may also cause swelling of the interfaces. Such interface swelling may occur, for example, when heat generated during operation of the BGA package 100 and adjacent surroundings of high temperature cause the moisture to expand. Consequently, delamination and/or cracking may result at the interface in contact with the solder resist layers 40.

In an effort to solve the above problems, one conventional fabricating technique may provide a solder resist layer with a concavo-convex shape to reinforce the adhesion between a resin sealing and the solder resist layer. However, this conventional technique may use PSR to form the solder resist layer, and therefore it may nevertheless suffer from the same shortcomings discussed above.

### SUMMARY

According to an example, non-limiting embodiment of the present invention a method may involve providing a substrate body having an upper surface and a lower surface. Circuit layers may be provided on the upper and the lower surfaces. A prepreg layer may be provided on the upper surface. The prepreg layer may only partially cover the circuit layer on the upper surface.

According to another example, non-limiting embodiment of the present invention, a PCB may include a substrate body having an upper surface and a lower surface. Circuit layers may be provided on the upper and the lower surfaces. A prepreg layer may be provided on the upper surface. The prepreg layer may only partially cover the circuit layer on the upper surface.

According to another example, non-limiting embodiment of the present invention a semiconductor package may include a PCB. The PCB may include a substrate body having an upper surface and a lower surface. Circuit layers may be provided on the upper and the lower surfaces. A prepreg layer may be provided on the upper surface. The prepreg layer may only partially cover the circuit layer on the upper surface. A semiconductor chip may be mounted on the prepreg layer and may be electrically connected to the circuit layer on the upper surface. A resin sealing may be provided on the upper surface of the PCB to encapsulate the semiconductor chip. Solder bumps may be provided on the lower surface and may be electrically connected to the semiconductor chip.

According to another example, non-limiting embodiment of the present invention, a method may involve providing at least one conductive substrate pad on a surface of a substrate body. A prepreg layer may cover the surface. The prepreg layer may have a window through which the at least one conductive substrate pad may be exposed.

According to another example, non-limiting embodiment of the present invention, a printed circuit board may include a substrate body having a surface supporting at least one conductive substrate pad. A prepreg layer may cover the surface. The prepreg layer may have a window through which the at least one conductive substrate pad may be exposed.

### BRIEF DESCRIPTION OF THE DRAWINGS

FIG. 1 is a plan view of a conventional PCB for a semiconductor package.

FIG. 2 is a sectional view taken along the line II-II of FIG. 1.

FIG. 3 is a sectional view of a semiconductor package implementing the conventional PCB of FIG. 1.

FIGS. 4 to 11 are schematic views illustrating the manufacture of a PCB for a semiconductor package in accordance with an example, non-limiting embodiment of the present invention.

FIG. 4 is a perspective view of a copper circuit layer that may be provided on a substrate body.

FIG. 5 is a sectional view taken along the line V-V of FIG. 4.

FIG. 6 is a perspective view of a prepreg that may be provided on the substrate body.

FIG. 7 is a perspective view of a copper foil that may be provided on the prepreg.

FIG. 8 is a sectional view taken along the line VIII-VIII of FIG. 7.

FIG. 9 is an enlarged sectional view of the part “A” of FIG. 8.

FIG. 10 is a sectional view of the substrate body after removing the copper foil.

FIG. 11 is a sectional view of a solder resist layer that may be provided on the substrate body.

FIG. 12 is a sectional view of a semiconductor package implementing the PCB of FIG. 11 in accordance with an example, non-limiting embodiment of the present invention.

FIG. 13 is an enlarged sectional view of the part “B” of FIG. 12.

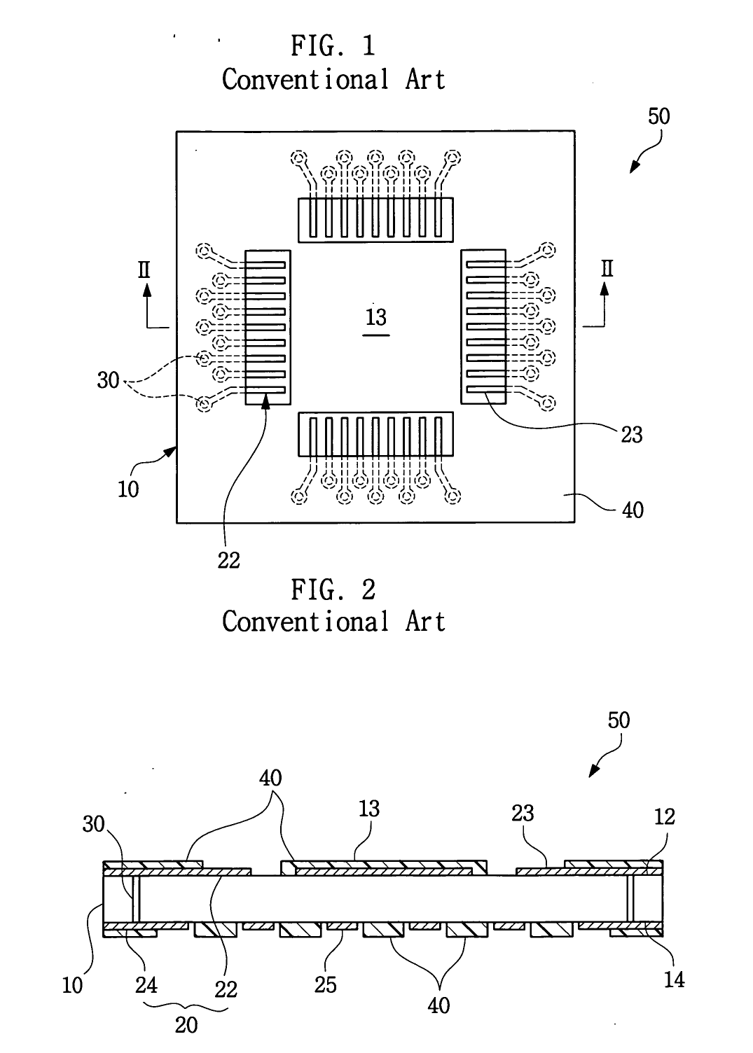

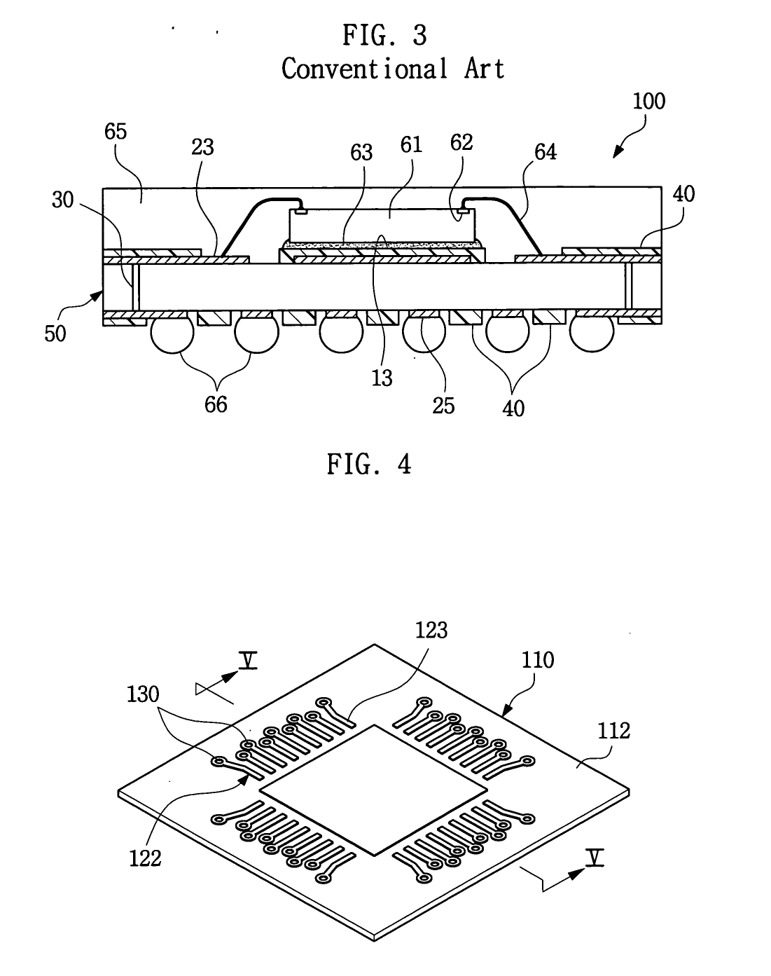

### DETAILED DESCRIPTION OF EXAMPLE EMBODIMENTS

Example, non-limiting embodiments of the present invention will be described in more detail with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention.

Well-known structures and processes are not described or illustrated in detail to avoid obscuring the essence of the present invention.

The figures are provided for illustrative purposes only and are not drawn to scale. Rather, for simplicity and clarity of illustration, the dimensions of some of the elements may be exaggerated relative to other elements. The figures, therefore, should not be interpreted as accurately reflecting the relative sizing or positioning of the corresponding structural elements that could be encompassed by an actual device manufactured according to the example embodiments of the invention. Like reference numerals are used for like and corresponding parts of the various drawings.

An element is considered as being mounted (or provided) “on” another element when mounted (or provided) either directly on the referenced element or mounted (or provided) on other elements overlaying the referenced element. Throughout this disclosure, the terms “upper” and “lower” are used for convenience in describing various elements or portions or regions of the elements as shown in the figures. These terms do not, however, require that the structure be maintained in any particular orientation.

FIGS. 4 to 11 are drawings showing manufacturing steps of a PCB 150 for a semiconductor package in accordance with an example embodiment of the present invention. In the above drawings, the same number is given to the same component.

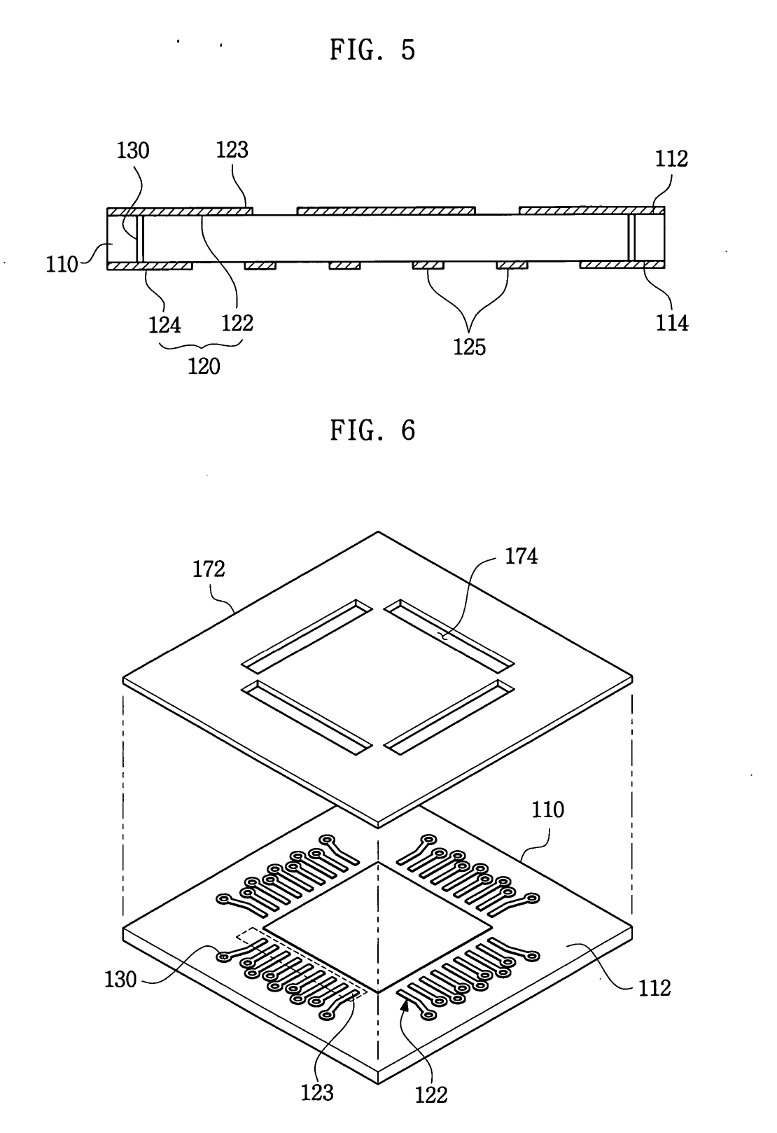

FIGS. 4 and 5 illustrate a substrate body 110 having an upper surface 112 and a lower surface 114. Copper circuit layers 120 may be provided on the upper and the lower surfaces 112 and 114. The substrate body 110 may be an insulating sheet fabricated from prepreg material. The copper circuit layers 120 may be formed, for example, by thermocompressing and patterning copper foils. Thermocompressing and patterning techniques are well known in this art.

The copper circuit layers 120 may include an upper circuit layer 122 provided on the upper surface 112 of the substrate body 110 and a lower circuit layer 124 provided on the lower surface 114 of the substrate body 110. The upper circuit layer 122 may be provided adjacent to a chip mounting area, which may be located (for example) in the center of the upper surface 112 of the substrate body 110. The upper circuit layer 122 may include substrate pads 123, which may be electrically connected to a semiconductor chip. The lower circuit layer 124 may include bump pads 125 on which solder bumps may be provided. The substrate pads 123 and the bump pads 125 may be electrically interconnected through via holes 130 piercing the substrate body 110.

In the illustrated embodiment, the substrate body 110 may be implemented in a single semiconductor package. In alternative embodiments, the substrate body 110 may be provided in a matrix shape that may be implemented in a plurality of semiconductor packages.

FIGS. 6 to 10 illustrate and example method of providing a prepreg layer 170 on the substrate body 110.

As shown in FIG. 6, a prepreg sheet 172 may be provided on the upper surface 112 of the substrate body 110. The prepreg sheet 172 may have windows 174 through which the substrate pads 123 may be exposed. By way of example only, the substrate pads 123 may be symmetrically arranged along sides of the substrate body 110. All of the substrate pads on a particular side may exposed through one of the windows 174. In alternative embodiments, the substrate pads 123 may be asymmetrically arranged on the substrate body 110.

In this example embodiment, the windows 174 of the prepreg sheet 172 may have an elongated rectangular shape along the sides of the prepreg sheet 172. In this case, the prepreg sheet 172 may be divided into a portion mounted on the periphery of the substrate body 110 and another portion mounted on the chip mounting area of the substrate body 110. In alternative embodiments, the shape of the windows 174 may be modified to have any geometric shape. Also, the prepreg sheet 172 may include any number of windows 174 that may be arranged in various fashions. For example, a single window 174 may be provided to expose all of the substrate pads 123 on the substrate body 110. The windows 174 provided in a given prepreg sheet 172 may expose the same (or a different) number of substrate pad 123. The windows 174 may be asymmetrically provided in the prepreg sheet 172.

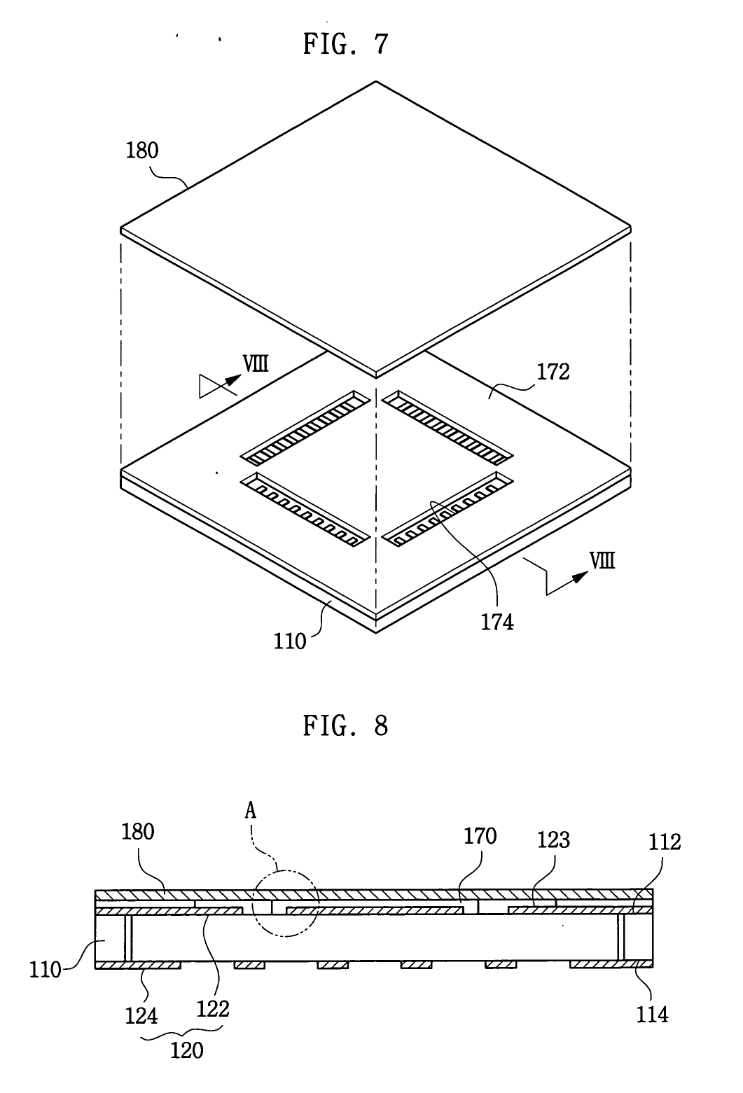

The prepreg sheet 172 is provided in B-stage. As is well known in this art, B-stage is an intermediate stage in the polymerization reaction of some thermosets in which the material may soften with heat and may be plastic and fusible. The prepreg sheet 172 may be attached to the upper surface 112 of the substrate body 110 by a thermocompressing process (described below with reference to FIGS. 7 and 8). During the thermocompressing process, the prepreg sheet 172 (in B-stage)may initially soften (via application of heat) and move and/or change shape slightly. Accordingly, the windows 174 may be formed a little larger than the desired size of the windows 174after the thermocompressing processes has been performed.

FIGS. 7 and 8illustrate an example thermocompressing process. Here, a copper foil 180 may be provided on the upper surface of the prepreg sheet 172. During the thermocompressing process, heat may be supplied so that the prepreg sheet 172 in B-stage may initially soften, and then may attach to the upper surface 112 of the substrate body by hardening. Sufficient heat may be applied so that the prepreg sheet 172 transitions from B-stage to C-stage. As is well known in this art, C-stage may be a final curing that may result in irreversible hardening. As a result, the thermocompressed prepreg sheet 172 may form a prepreg layer 170 that may protect the upper circuit layer 122.

By way of example only, the prepreg layer 170 may be fabricated from the same material as the substrate body 110. In alternative embodiments, the prepreg layer 170 and the substrate body 110 may be fabricated from different materials. The prepreg layer 170 may have increased adhesive strength with the substrate body 110 and the upper circuit layer 122, and reduced moisture absorption characteristics, as compared to conventional PSR materials.

The prepreg layer 170 may be formed via similar manufacture techniques and those employed to fabricate as a multi-layer PCB. But there are some notable differences. For example, a patterning process of the copper foil 180, which may be employed to fabricated the multi-layer PCB, may be eliminated. Also, the prepreg layer 170 may serve as a protection layer for the upper circuit layer 122.

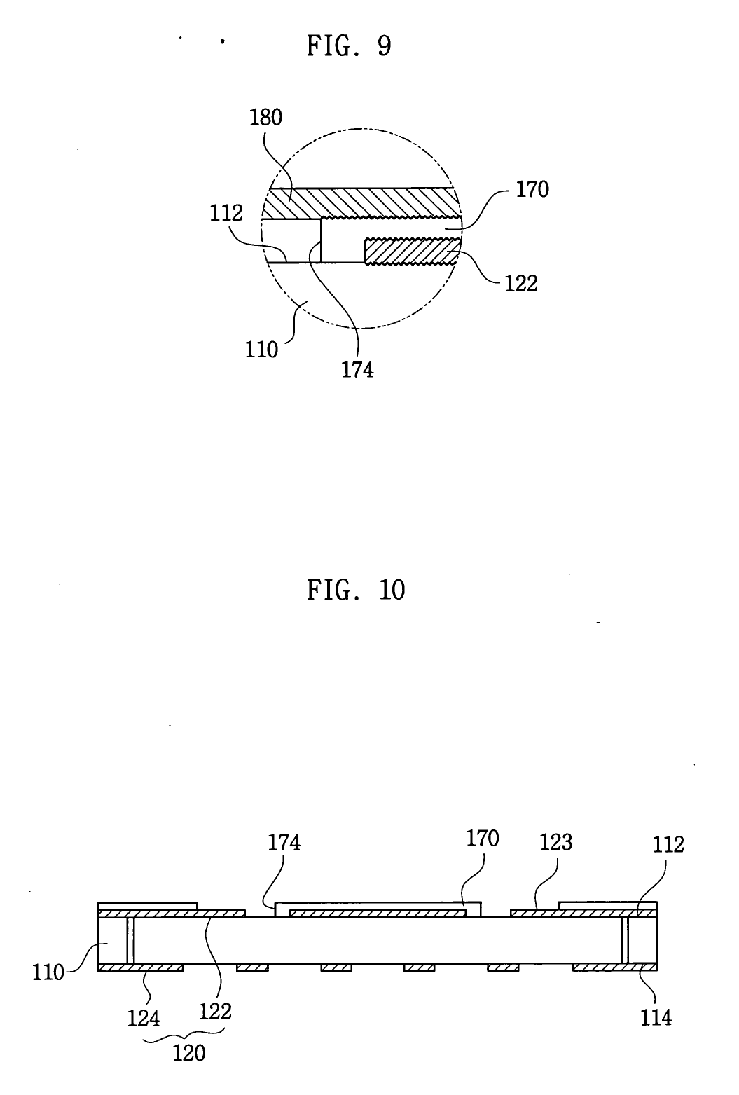

When the prepreg sheet 172 is thermocompressed with the copper foil 180, as shown in FIG. 9, the surfaces of the prepreg sheet 172 may become attached to the upper circuit layer 122 and the copper foil 180 via a penetration effect. As a result, the interface between the prepreg layer 170 and the copper foil 180 and the interface between the prepreg layer 170 and the upper circuit layer 122 may have non-planar contours. For example, the interfaces may have alternating concave and convex portions. As shown in FIG. 9, the concave and convex portions may be uniformly provided (i.e., a uniform concavo-convex shape). In alternative embodiments, the interface contours may include randomly shaped protrusions and recesses. The non-planar interface contours may increase adhesion between the prepreg layer 170 and the upper circuit layer 122.

As shown in FIG. 10, the copper foil (180 in FIG. 9) may be removed from the prepreg layer 170. The copper foil 180 may be removed by an etching process, for example.

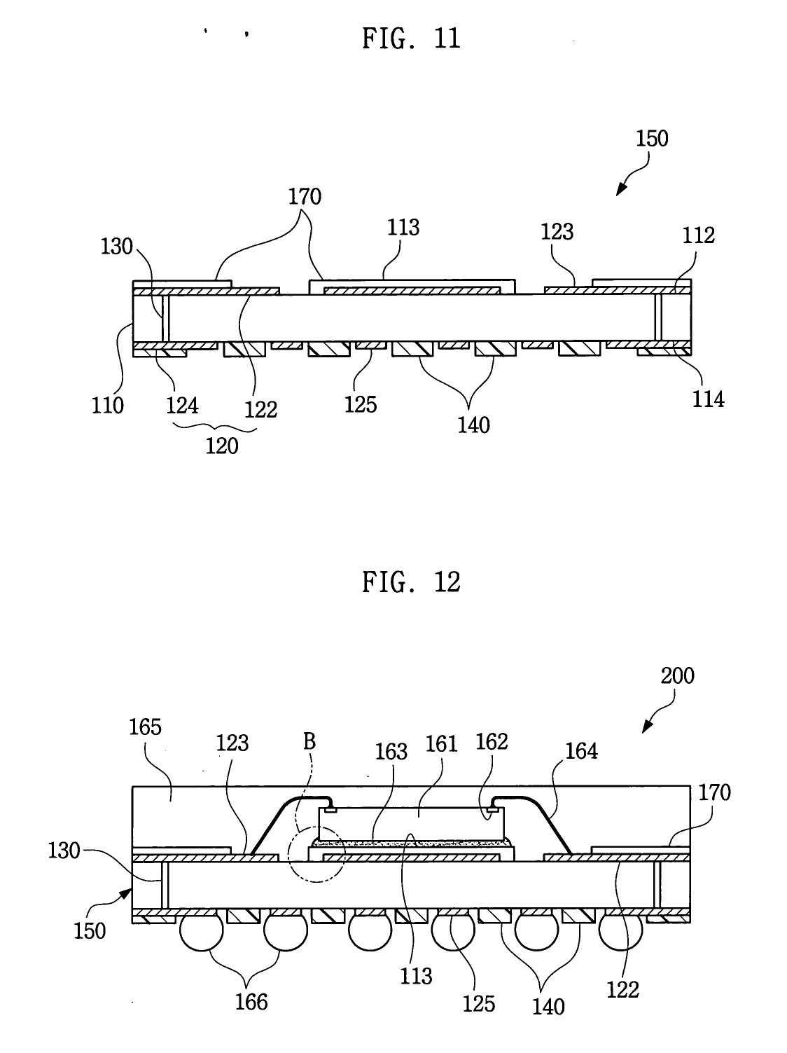

As shown in FIG. 11, a solder resist layer 140 may be provided on the lower surface 114 of the substrate body 110. The solder resist layer 140 may be formed by providing PSR onto the lower surface 114 of the substrate body 110, and patterning the PSR so that the bump pads 125 of the lower circuit layer 124 may be exposed. In alternative embodiments, the solder resist layer 140 may be dispensed with in favor of a prepreg layer.

It may be advantageous to provide the solder resist layer 140 (instead of a prepreg layer) on the lower surface 114 of the substrate body 110. For example, the solder resist layer 140, which may be provided on the lower surface of the substrate body 110, may not suffer from the problems of moisture absorption and/or delamination that may be experienced when a solder resist layer is provided on the upper surface of the substrate body (as in the conventional art). Additionally, as compared to a prepreg layer (which may be provided via a thermocompressing process), a solder resist layer may be more easily patterned so that the individual bump pads 125 of the lower circuit layer 124 may be exposed from the lower surface of the PCB 150. The solder resist layer 140 may be formed by a patterning process, which may enable a fine processing to expose the individual bump pads 125 from the lower surface of the PCB 150.

In the example embodiment, the solder resist layer 140 may be patterned so that the bump pads 125 may be fully exposed. In alternative embodiments, the solder resist layer may be patterned so that only a portion of the bump pad may be exposed. The former may be referred to as a non solder mask defined (“NSMD”) type PCB, and the latter may be referred to as a solder mask defined (“SMD”)) type PCB.

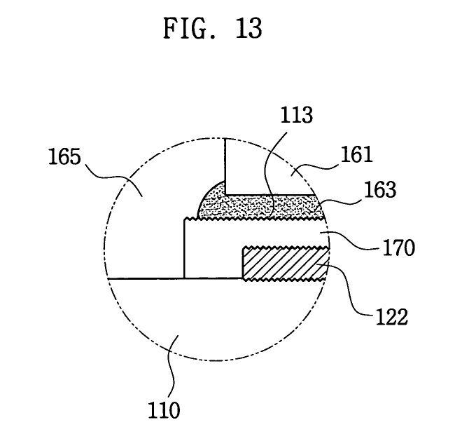

FIGS. 12 and 13 illustrate an example semiconductor package 200 that may implement the PCB 150 of FIG. 11. The semiconductor package 200 may be a BGA package (for example). Solder bumps 166 may be provided on the lower surface of the PCB 150. A semiconductor chip 161 may be mounted on the upper surface of the PCB 150. The semiconductor chip 161 may be mounted on a chip mounting area 113 of the PCB 150 via an adhesive 163, for example. Chip pads 162 of the semiconductor chip 161 and the substrate pads 123 of the PCB 150 may be electrically interconnected by bonding wires 164, for example. The semiconductor chip 161 and the bonding wires 164 may be surrounded by a resin sealing 165. The resin sealing 165 may be fabricated from a liquid molding resin, for example. Additionally, the solder bumps 166 may be provided on individual bump pads 125 of the PCB 150.

As shown in FIG. 13, the chip mounting area 113 of the prepreg layer 170 may have a non-planar contour (e.g.,, concavo-convex shapes may be uniformly provided on the surface of the chip mounting area 113). This non-planar contour may increase the area of the adhesion interface between the adhesive 163 and the chip mounting area 113, and thus may increase the adhesion strength between the semiconductor chip 161 and the prepreg layer 170.

Additionally, increased adhesion strength between the resin sealing 165 and the prepreg layer 170 may be obtained because the interface between the resin sealing 165 and prepreg layer 170 at the periphery of the semiconductor chip 161 may have a non-planar contour (e.g., a uniform concavo-convex shape).

Increased adhesion strength between the upper circuit layer 122 and the prepreg layer 170, as well as increased adhesion strength between an upper surface of the substrate body 110 and the prepreg layer 170 may be obtained because the prepreg layer 170 may be formed by a thermocompressing process, for example.

As compared to PSR materials, the prepreg layer 170 may have a relatively low moisture absorbing characteristic, and may thereby restrain the occurrence of delamination and/or cracking due to moisture absorption at the interface between a semiconductor chip 150 and the PCB161.

The prepreg layer 170 may be fabricated from the same prepreg material that may be commonly used to fabricate conventional PCBs, which may provide economic advantages in terms of reduced development and/or manufacture expenditures.

The example, non-limiting embodiments of the present invention have been disclosed for illustrative purposes only. It will be appreciated by those skilled in the art that various substitutions, modifications, and/or changes are possible, without departing from the scope and spirit of the invention as pointed out in the accompanying claims. This invention should not be construed as limited to the example embodiments set forth herein or in the accompanying drawings.

What is claimed is:

1. A method comprising:
providing a substrate body having an upper surface and a lower surface;
providing circuit layers on the upper and the lower surfaces; and
providing a prepreg layer on the upper surface, the prepreg layer covering the circuit layer on the upper surface.

2. The method of claim 1, wherein the circuit layers include an upper circuit layer having substrate pads, and a lower circuit layer electrically connected to the upper circuit layer and having bump pads.

3. The method of claim 2, wherein providing the prepreg layer comprises:
mounting a prepreg sheet on the upper surface of the substrate body, the prepreg sheet having windows through which the substrate pads are exposed;
thermocompressing a foil on the prepreg sheet to form the prepreg layer; and
removing the foil from the prepreg layer.

4. The method of claim 2, further comprising providing a solder resist layer on the lower surface of the substrate body, the bump pads being exposed through the solder resist layer.

5. The method of claim 4, further comprising providing via holes through the substrate body to electrically connect the upper circuit layer to the lower circuit layer.

6. A printed circuit board comprising:
a substrate body having an upper surface and a lower surface;
circuit layers provided on the upper and the lower surfaces; and
a prepreg layer provided on the upper surface, the prepreg layer covering the circuit layer on the upper surface.

7. The printed circuit board of claim 6, wherein the circuit layers include:
an upper circuit layer having substrate pads; and
a lower circuit layer electrically connected to the upper circuit layer and having bump pads.

8. The printed circuit board of claim 7, wherein the prepreg layer covers the upper surface of the substrate body except the substrate pads.

9. The printed circuit board of claim 7, further comprising a solder resist layer covering the lower surface except the bump pads.

10. The printed circuit board of claim 9, wherein the upper circuit layer and lower circuit layer are electrically interconnected by via holes piercing the substrate body.

11. A semiconductor package comprising:
a printed circuit board including
a substrate body having an upper surface and a lower surface;
circuit layers provided on the upper and the lower surfaces; and
a prepreg layer provided on the upper surface, the prepreg layer covering the circuit layer on the upper surface;
a semiconductor chip mounted on the prepreg layer and electrically connected to the circuit layer on the upper surface;
a resin sealing provided on the upper surface of the printed circuit board to encapsulate the semiconductor chip; and
solder bumps provided on the lower surface and electrically connected to the semiconductor chip.

12. The semiconductor package of claim 11, wherein the circuit layers comprise:
an upper circuit layer having substrate pads electrically connected to the semiconductor chip; and
a lower circuit layer having bump pads supporting the solder bumps.

13. The semiconductor package of claim 12, wherein the prepreg layer covers the upper surface of the substrate body except the substrate pads.

14. The semiconductor package of claim 12, further comprising a solder resist layer covering the lower surface except the bump pads.

15. The semiconductor package of claim 14, wherein the upper circuit layer and lower circuit layer are electrically interconnected by via holes piercing the substrate body.

16. The manufacturing method of claim 1, wherein the substrate body and the prepreg layer are fabricated from the same material.

17. The printed circuit board of claim 6, wherein the substrate body and the prepreg layer are fabricated from the same material.

18. The semiconductor package of claim 11, wherein the substrate body and the prepreg layer are fabricated from the same material.

19. The manufacturing method of claim 1, wherein the prepreg layer only partially covers the circuit layer on the upper surface.

20. The printed circuit board of claim 6, wherein the prepreg layer only partially covers the circuit layer on the upper surface.

21. The semiconductor package of claim 11, wherein the prepreg layer only partially covers the circuit layer on the upper surface.

22. A method comprising:
providing at least one conductive substrate pad on a surface of a substrate body; and
covering the surface with a prepreg layer, the prepreg layer having a window through which the at least one conductive substrate pad is exposed.

23. A printed circuit board comprising:
a substrate body having a surface supporting at least one conductive substrate pad; and
a prepreg layer covering the surface, the prepreg layer having a window through which the at least one conductive substrate pad is exposed.
